(19) United States
(12) Patent Application Publication
(10) Pub. No.: US 2005/0072359 A1
(43) Pub. Date: Apr. 7, 2005

(54) Mask frame assembly for depositing a thin layer of an organic electroluminescent device and method for depositing a thin layer using the same

(76) Inventor: Seon-Hee Kim, Ulsan-si (KR)

Correspondence Address: McGuire Woods LLP, Suite 1800, 1750 Tysons Boulevard, McLean, VA, 22102, US

(21) Appl. No.: 10/956,030

(22) Filed: Oct. 4, 2004

(30) Foreign Application Priority Data
Oct. 4, 2003 (KR) 2003-68989

(51) Int. Cl. C23C 16/00

(52) U.S. Cl. 118/720; 427/69; 427/282; 427/248.1; 118/721

(57) ABSTRACT

A mask frame assembly for depositing a thin layer of an organic electroluminescent device is taught. The mask frame assembly may include the following: a main mask formed with patterns corresponding to a plurality of unit cells; an icon mask (having icon patterns) disposed on the main mask to correspond to one or more openings formed in the main mask; and a mask frame formed with an opening corresponding to the main mask and connected to the main mask and icon mask.

This application claims the priority of Korean Patent Application No. 2003-68989, filed on Oct. 4, 2003, in the Korean Intellectual Property Office, the disclosure of which is incorporated herein in its entirety by reference.

### BACKGROUND OF THE INVENTION

1. Field of the Invention

The present invention relates to a mask frame assembly for depositing a thin layer of an organic electroluminescent device. More particularly, the invention relates to a mask frame assembly in which a main mask formed with patterns corresponding to cells and an icon mask formed with icon patterns are separately included. The present invention also relates to a method for depositing a thin layer using the same.

2. Description of the Related Art

An electroluminescent device is an active lighting device that has advantages such as quick response speed, wide viewing angle, and high-quality contrast. Such electroluminescent devices include organic electroluminescence devices and inorganic electroluminescence devices. This distinction is based on the kind of material (organic or inorganic) that forms the electroluminescent layer. An organic electroluminescent device has better resolution and quicker response speed than an inorganic electroluminescent device. Also, it has better capability as a color display.

An organic electroluminescent device may include the following: a transparent substrate; first electrodes (for example, anode electrodes) having predetermined patterns formed on said transparent substrate; an organic luminescent layer formed on said transparent substrate having the electrodes by the vacuum deposition method; and second electrodes (for example, cathode electrodes) formed in a crosswise direction to said first electrodes on said organic luminescence layer.

In the process of manufacturing the organic electroluminescent device, the first electrodes are commonly made of ITO. The patterning of the ITO may be achieved by photolithography. In such a method, the ITO layer may be patterned with etching liquid including ferric chloride by means of the wet etching. If the second electrodes (the cathode electrodes) are etched by photolithography, however, moisture may be introduced into the gap formed between the organic luminescent layer and the second electrodes during the steps of removing the photoresist and etching the second electrodes. Thus, the capability and life-span of the organic electroluminescent device may be degraded.

One attempt to solve this problem includes a deposition method in which the organic electroluminescent material for forming the organic electroluminescent layer and the material for forming the second electrode are prepared by deposition.

In the process of manufacturing the organic electroluminescent device using deposition, the first electrodes having strip pattern may be formed on a transparent substrate using sputtering and photolithography. Then, the electroluminescent layer may be formed over the first electrodes on the transparent substrate. Afterward, a mask having the same pattern as the second electrodes may be disposed on the electroluminescent layer and the material for forming the second electrodes may be deposited.

Korean Patent Application No. 2000-0060589 describes a mask for use in the deposition of the electroluminescent layer, the electroluminescent device and the manufacturing method of the electroluminescent device using the mask.

The disclosed mask for deposition includes strip-patterned slots at predetermined intervals formed in a sheet-type main body.

Korean Patent Application No. 1998-0071583 discloses another mask in the shape of meshes including slit portions and bridge portions formed in a metallic sheet.

Japanese Patent Application No. 2000-12238 discloses another mask including an electrode mask portion and a pair of terminal mask portion. The electrode mask portion includes a width corresponding to second electrodes (for example, cathode electrodes) and has marking portions on parallel stripes and connecting portions connecting both ends of the markings.

FIG. 1 is a schematic exploded view of a mask assembly for mass-production of the electroluminescent layer.

As shown in FIG. 1, the mask assembly may include a mask 11 and a mask frame 12 to which the mask 11 is attached. The mask frame 12 includes an opening 16 and the mask 11 has an area corresponding to that opening 16. The mask 11 is clipped to the mask frame 12. When being clipped, tension force may be imposed on the mask 11.

The mask 11 may be formed with a plurality of unit cells 15 and each of the unit cells 15 may include fine-pitch patterns 13 and icon patterns 14. The fine-pitch patterns 13 may include a number of slits formed by puncturing the mask, and strips formed between the slits. The icon pattern 14 may also be formed by puncturing the mask and may have a predetermined shape, such as a letter, number, or other character or character string.

In the process of the deposition of the electroluminescent layer using the mask with above-described structures, the mask 11 contacts the surface of the substrate with the first electrodes while in a vacuum chamber. The organic material gas evaporated from a crucible containing the organic material passes through the fine-pitch pattern 12 and the icon pattern 14 and is deposited on the substrate (not shown) in a predetermined shape.

As described herein before, because the mask 11 is manufactured in such a manner that the fine-pitch patterns 13 and the icon patterns 14 are simultaneously formed, some problems may arise. In general, if a display has the same size, the design for the pine-pitch pattern 13 does not need to change. However, frequently, the design for the icon patterns 14 may be changed in accordance with a customer's demands. Accordingly, the whole mask 11 would need to be changed every time the icon patterns 14 are changed. This increases manufacturing costs and extends the manufacturing period. Further, even if the icon patterns 14 are same, but the colors are different, the number of masks corresponding to those colors may have to be increased, leading to the same problems.

### SUMMARY OF THE INVENTION

The present invention provides an improved mask frame assembly for depositing electroluminescent layer. The mask frame assembly may include a mask with fine-pitch patterns and another separable mask with icon patterns.

The present invention also provides a method for depositing an electroluminescent layer using a mask frame assembly including a mask with fine-pitch patterns and another separable mask with icon patterns.

To these ends, the present invention may provide a mask frame assembly for depositing thin layer of an organic electroluminescent device. The mask frame assembly may include a main mask formed with patterns corresponding to a plurality of unit cells as well as an icon mask disposed on the main mask. The icon mask may be designed to correspond to one or more openings formed in the main mask and it itself may have icon patterns. The mask frame assembly may also include a mask frame formed with an opening corresponding to the main mask. The main mask and the icon mask may be coupled to the mask frame.

According to an aspect of the present invention, the main mask may be coupled to the mask frame and the icon mask may detachably coupled to the mask frame.

The present invention may also provide a method for depositing a thin film layer using a mask frame assembly for depositing organic electroluminescent material. The method may comprise: preparing a main mask formed with patterns corresponding to unit cells and openings located at least at one side of the patterns; coupling the main mask to the mask frame; detachably connecting an icon mask (formed with icon patterns) that corresponds to one of the openings of the main mask; installing a mask frame assembly including the main mask and the icon mask into a vacuum chamber; and depositing evaporated organic material onto a substrate while the substrate approximately contacts said mask frame assembly.

### BRIEF DESCRIPTION OF THE DRAWINGS

FIG. 1 is a schematic exploded view of a conventional mask frame assembly for depositing an electroluminescent layer of an organic electroluminescent device.

FIG. 2 is a schematic exploded view of a mask frame assembly according to the present invention for depositing an electroluminescent layer of an organic electroluminescent device.

FIG. 3 shows a method for depositing a layer using the mask frame assembly shown in FIG. 2.

### DETAILED DESCRIPTION OF THE INVENTION

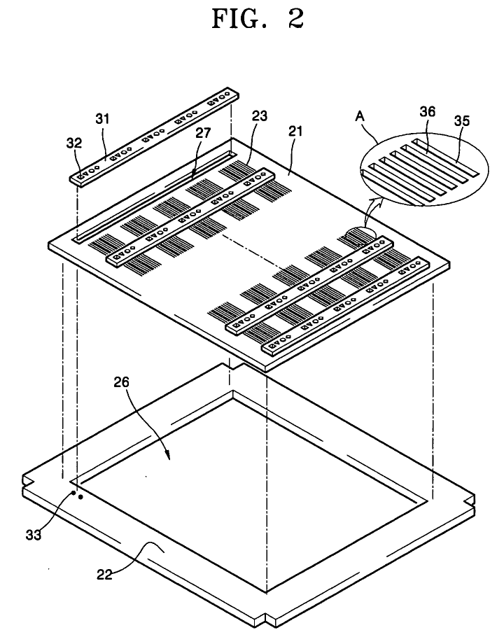

As shown in FIG. 2, a mask frame assembly of the present invention may includes a main mask 21 formed with patterns 23 corresponding to each of the desired unit cells; icon masks 31 respectively disposed on the corresponding openings 27 formed in the main mask 21 and including icon patterns 32; and a mask frame 22 formed with an opening 26 corresponding to the main mask 21. The mask frame 22 may be coupled to the mask 21 and the icon mask 31 as shown.

The main mask 21 may be formed with a plurality of the patterns 23 and a plurality of the openings 27. Each of the patterns 23 may form a unit cell. As can be seen from an enlarged view of the pattern 23 indicated with “A”, the pattern 23 may include a plurality of parallel slits 35, all of which may be formed by puncturing (or otherwise patterning) the main mask 21, as well as a plurality of strips 36 resultantly formed between the slits 35. Organic material can be deposited through the slits 35 onto a substrate (not shown) disposed under the main mask 21. The main mask 21 may be attached to the mask frame 22 by means of welding, or by any other suitable means.

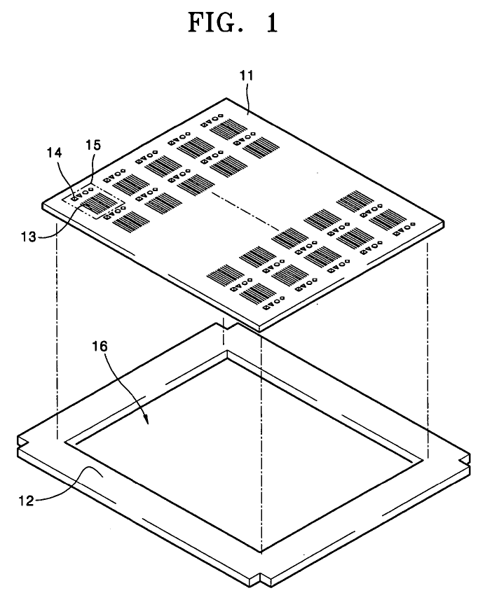

The openings 27 may be formed between groups of patterns 23 disposed in a row. The location at which the openings 27 are created may correspond to the desired location of the icon patterns 14, as shown in FIG. 1. The openings 27 formed in the main mask 21 may be formed in such a manner that the openings 27 do not interfere with the disposition of the organic material through the icon mask 31 when the icon masks 31 are placed into (or onto) the openings 27.

As shown in the drawings, each of the icon masks 31 may correspond to each of the respective openings 27. The icon mask 31 may be formed with a plurality of icon patterns 32. A set of the icon patterns 32 may be assigned to each of the patterns 23. The icon mask 31 may be disposed so as to correspond to the opening 27 of the main mask 31. Both ends of the icon mask 21 may be detachably clipped to clipping points 33 of the mask frame 2. Many kinds of methods may be applied for clipping. For instance, clipping can utilize a set of clips that have reliable clipping force. Any other suitable detachable connection technique may also be used.

The icon patterns 32 formed in the icon mask 31 may be modified in their shapes in accordance with a customer's request, or for any other reason. For instance, when a customer requests a new model (with corresponding changes to the icons associated with the model), it may be possible to simply replace the icon mask 31 without having to change the whole main mask 21. Further, in order to obtain color through the icon pattern 32 and to cope with change of color, different icon masks may be included for depositing, for example, red, green, and blue.

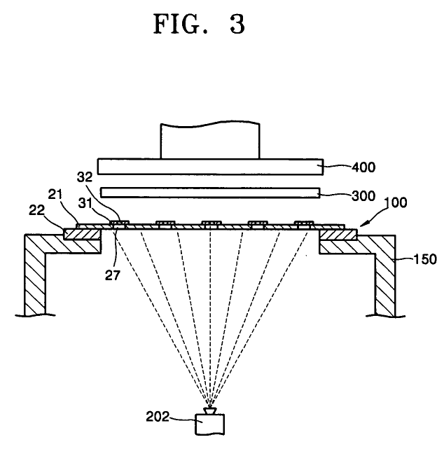

As shown in FIG. 3, a mask frame assembly 100 may be fixed on a table 150 installed in a vacuum chamber (not shown). In order to deposit the red, green and blue layers of the organic electroluminescent device, the mask frame assembly 100 may be installed opposite a crucible 202 containing the organic material and a substrate 300 for receiving the deposition. The substrate 300 may be pressed by a magnet unit 400, which may serves to place the mask frame assembly 100 in contact with the substrate 300. Using this method, the mask 21 can tightly contact the substrate 300.

Once the mask has been initialized, the organic material in the crucible 202 evaporates and is deposited on the unmasked portions of the substrate 300. The evaporated organic material may be deposited through the patterns formed in the main mask 21 and the icon patterns formed in the icon mask 31.

In the present invention, the mask frame assembly for depositing thin layer of the organic electroluminescent device may include a separate main mask and icon mask. Thus it may be possible, when the icon pattern is to be changed, to redesign and replace only the icon mask portion of the device. Accordingly, time and cost for production can be reduced. Also, it may be possible to cope immediately with a customer's demand and to improve productivity.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A mask frame assembly for depositing one or more thin layers of an organic electroluminescent device, comprising:
a main mask with patterns corresponding to a plurality of unit cells, and provided with an opening on the patterns;
an icon pattern-bearing mask with patterns corresponding to icons;
wherein the icon pattern-bearing mask is disposed on the main mask and corresponds to the opening formed in the main mask; and
a mask frame formed with an opening corresponding to the main mask and coupled to the main mask and the icon pattern-bearing mask.

2. The mask frame assembly of claim 1, wherein the main mask is directly coupled to the mask frame and the icon pattern-bearing mask is detachably coupled to the mask frame.

3. The mask assembly of claim 2, wherein the icon pattern-bearing mask is detachably coupled using clips.

4. The mask assembly of claim 1, wherein the icon pattern-bearing mask is adapted to pattern icons corresponding to geometric shapes.

5. The mask assembly of claim 1, wherein the icon pattern-bearing mask is adapted to pattern icons corresponding to characters.

6. The mask assembly of claim 1, wherein the main mask is welded to the mask frame assembly.

7. The mask assembly of claim 1, wherein the patterns are punched patterns.

8. The mask assembly of claim 1, wherein the icons are selected based on customer demands.

9. The mask assembly of claim 1, wherein the mask frame is directly coupled to the main mask and is directly coupled to the icon pattern-bearing mask.

10. The mask assembly of claim 1, wherein the mask frame is directly coupled to the main mask and is indirectly coupled to the icon pattern-bearing mask.

11. A method for depositing one or more thin layers using a mask frame assembly for depositing organic electroluminescent, comprising:
forming a main mask with patterns corresponding to a plurality of unit cells and one or more openings located at one or more sides of the patterns;
coupling the main mask to a mask frame;
forming an icon mask with icon patterns;
placing the icon mask corresponding to the openings of the main mask;
detachably coupling the icon mask to the main mask; and
installing a mask frame assembly including the main mask and the icon mask into a vacuum chamber;
placing a substrate in approximate contact with the mask frame assembly; and
depositing evaporated organic material onto the substrate.

12. The method of claim 11, wherein coupling the main mask to the mask frame comprises welding the main mask to the mask frame.

13. The method of claim 11, wherein detachably coupling the icon mask to the main mask comprises clipping the icon mask to the main mask.

14. The method of claim 11, wherein forming an icon mask with icon patterns comprises forming icon patterns corresponding to geometrical shapes.

15. The method of claim 11, wherein forming an icon mask with icon patterns comprises forming icon patterns corresponding to characters.

16. The method of claim 11, wherein forming a main mask with patterns comprises punching the patterns into the mask.

17. The method of claim 11, wherein forming an icon mask with icon patterns comprises punching the icon patterns into the mask.

18. The method of claim 11, further comprising selecting the icon patterns based on customer demands.

19. The method of claim 11, wherein the mask frame is directly coupled to the main mask and is directly coupled to the icon pattern-bearing mask.

20. The method of claim 11, wherein the mask frame is directly coupled to the main mask and is indirectly coupled to the icon pattern-bearing mask.
